(19) United States
(12) Patent Application Publication
(10) Pub. No.: US 2003/0025184 A1
(43) Pub. Date: Feb. 6, 2003

(54) Semiconductor device and method for manufacturing the same

(75) Inventor: Yukio Morozumi, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/202,837

(22) Filed: Jul. 26, 2002

(30) Foreign Application Priority Data
Aug. 3, 2001 (JP) 2001-236239

(51) Int. Cl. H01L 23/02

(52) U.S. Cl. 257/678

(57) ABSTRACT

The invention provides a highly reliable, small sized stacked level semiconductor device with high density at low costs, and also methods for manufacturing the same. The semiconductor device can include a second semiconductor chip that is disposed on a surface of a first semiconductor chip. The semiconductor device can also include metal posts for taking out electrodes formed on a surface of the first semiconductor chip, metal posts for taking out electrodes formed on a surface of the second semiconductor chip, and a resin that seals the surface of the first semiconductor chip, the metal posts, the second semiconductor chip and the metal posts. Accordingly, the present invention can provide highly reliable, small sized stacked level semiconductor devices at low costs.

### BACKGROUND OF THE INVENTION

1. Field of Invention

The present invention relates to semiconductor devices and methods for manufacturing the same. More particularly, the present invention to a semiconductor device that is reduced in size to a CSP (Chip Size Package) level, and a method for manufacturing the same.

2. Description of Related Art

With further size-reduction of mobile telephones and information terminals in recent years, there are demands in smaller and lighter parts to be mounted on printed circuit boards, and also, semiconductor devices, such as LSIs, are required to achieve a high mounting density with a chip stacked layered structure at a CSP level. Conventional art, for example, Japanese laid-open patent application HEI 11-204720 describes a stacked level CSP type semiconductor device shown in FIG. 12. As shown, diced first and second semiconductor chips 51 and 52 are bonded onto a dielectric substrate 55 having mounting external terminals 53 through dielectric adhesive layers 57 and 59 with device forming surfaces thereof face-up. Electrode pads on each of the semiconductor chips are connected to wiring sections 58 on the dielectric substrate 55 using wires 54 composed of Au, Al or the like, which are then sealed by a resin 56.

Also, as indicated in “Nikkei Micro Device” February issue on pages 38-67, or “Electronic Material” September issue on pages 21-85 in 1999, wafer level CSP type semiconductor devices that integrate a wafer processing process and a package assembly process are provided. They may be characterized in that, by reducing the number of parts, such as interposers and the number of processing steps, compared to conventional CSP types that are manufactured from single chips, the manufacturing cost is lowered, and the total cost of packages is lowered.

### SUMMARY OF THE INVENTION

The current stacked level CSP type semiconductor devices that use wires are also aiming at further miniaturization. However, in view of bulging portions of the wires, the upper surface and the side surface of the semiconductor chips need to be sealed by resin in an overlapping manner. Thus, there is a demand toward further miniaturization. Also, due to the capability of the wire bonding apparatus, control of wire pitches and spatial control over the wire configuration are difficult. Therefore, such semiconductor devices are not suitable for multiple-pin packages of large size LSIs. Also, difficulties resulting from very fine pitches and stresses of sealing resin cause wires to contact with other wires or with end faces of the semiconductor chips, which result in problems in the yield and reliability. Also, the wire bonding amounts to a relatively high cost.

On the other hand, the wafer level CSP type semiconductor devices have an advantage as they can be miniaturized to a generally chip size as viewed in plane. However, since it is difficult to form stacked layers, there are certain limitations in achieving a higher mounting density although it is desired.

The present invention has been made in view of the circumferences described above, and can provide reliable, small sized stacked level semiconductor devices at low costs, and methods for manufacturing the same.

The invention can provide a semiconductor device wherein a second semiconductor chip is disposed on a surface of a first semiconductor chip. The semiconductor device can include a first metal post for taking out an electrode, formed on a surface of the first semiconductor chip, a second metal post for taking out an electrode, formed on a surface of the second semiconductor chip, and a resin that seals the surface of the first semiconductor chip, the first metal post, the second semiconductor chip and the second metal post.

In the semiconductor device described above, the second semiconductor chip can be mounted on the first semiconductor chip having the first metal post formed thereon, and the surface of the first semiconductor chip and the second semiconductor chip are covered and sealed by a resin. By this, a highly reliable wire-less stacked level CSP type semiconductor device in small size and high density can be obtained at low costs.

Also, the semiconductor device in accordance with the present invention may further include mounting external terminals disposed on the first metal post and the second metal post, respectively.

Also, in the semiconductor device in accordance with the present invention, at least one of the first metal post and the second metal post may be formed with a plated film.

Also, in the semiconductor device in accordance with the present invention, at least one of the first metal post and the second metal post may be formed with a metal ball.

Also, in the semiconductor device in accordance with the present invention, the mounting external terminal may preferably be formed with a metal ball.

Also, in the semiconductor device in accordance with the present invention, the first metal post may preferably be connected to a pad formed within the first semiconductor chip through a re-wiring layer, and the second metal post may preferably be connected to a pad formed within the second semiconductor chip through a re-wiring layer.

The present invention can also provide a semiconductor device wherein a plurality of semiconductor chips are stacked in layer on a surface of a semiconductor chip. The semiconductor device can include a metal post for taking out an electrode formed on a surface of each of the semiconductor chips, and a resin that seals the surface of the semiconductor chip and the metal posts.

Also, the semiconductor device in accordance with the present invention may further include mounting external terminals disposed on the metal posts.

Also, in the semiconductor device in accordance with the present invention, at least one of the metal posts may be formed with a plated film.

Also, in the semiconductor device in accordance with the present invention, at least one of the metal posts may be formed with a metal ball.

Also, in the semiconductor device in accordance with the present invention, the mounting external terminals may be formed with metal balls.

Also, in the semiconductor device in accordance with the present invention, the metal posts may preferably be connected to pads formed within the semiconductor chips through re-wiring layers.

The present invention can include semiconductor device wherein a second semiconductor chip is disposed on a surface of a first semiconductor chip. The semiconductor device can include a first mounting external terminal formed on a surface of the first semiconductor chip, a second mounting external terminal formed on a surface of the second semiconductor chip, and a resin that seals the surface of the first semiconductor chip, the first mounting external terminal, the second semiconductor chip and the second mounting external terminal. Surfaces of the first mounting external terminal and the second mounting external terminal can be exposed through the resin.

Also, in the semiconductor device in accordance with the present invention, the first mounting external terminal and the second mounting external terminal may preferably be formed with metal balls, respectively.

Also, in the semiconductor device in accordance with the present invention, the first mounting external terminal may preferably be connected to a pad formed within the first semiconductor chip through a re-wiring layer, and the second mounting external terminal may preferably be connected to a pad formed within the second semiconductor chip through a re-wiring layer.

A method for manufacturing a semiconductor device can include the steps of preparing a first semiconductor chip wherein a first metal post for taking out an electrode is formed on a surface thereof and a second semiconductor chip wherein a second metal post for tanking out an electrode is formed on a surface thereof, and disposing the first semiconductor chip on a supporting substrate through an adhesive layer. Further, the method can include disposing the second semiconductor chip on a surface of the first semiconductor chip through an adhesive layer, sealing the supporting substrate, the first semiconductor chip, the first metal post, the second semiconductor chip, and the second metal post with a resin, and removing the resin by a specified amount to expose surfaces of the respective first metal post and second metal post.

In the method for manufacturing a semiconductor device, the second semiconductor chip is disposed on the first semiconductor chip having the first metal post formed thereon, and the surface of the first semiconductor chip and the second semiconductor chip are covered and sealed by a resin. By this, a highly reliable wire-less stacked level CSP type semiconductor device in small size and high density can be manufactured at low costs.

Also, the method for manufacturing a semiconductor device in accordance with the present invention may further include the step of, after the step of exposing, disposing mounting external terminals on surfaces of the respective first metal post and second metal post.

A method for manufacturing a semiconductor device can include the steps of preparing a semiconductor wafer wherein a first metal post for taking out an electrode is formed on a surface of each of a plurality of chip regions, and preparing a semiconductor chip wherein a second metal post for taking out an electrode is formed on a surface thereof. Further, the method can include disposing the semiconductor chip on each of the chip regions of the semiconductor wafer through an adhesive layer, sealing the semiconductor wafer, the first metal post, the semiconductor chip and the second metal post with a resin, removing the resin by a specified amount to expose surfaces of the respective first metal post and second metal post.

Also, the method for manufacturing a semiconductor device in accordance with the present invention may further include the step of, after the step of exposing, disposing mounting external terminals on surfaces of the respective first metal post and second metal post.

Also, the method for manufacturing a semiconductor device in accordance with the present invention may further include the step of, after the step of disposing the mounting external terminals, dividing the semiconductor wafer into individual chips.

Also, in the method for manufacturing a semiconductor device in accordance with the present invention, the step of preparing the semiconductor wafer may include the steps of forming a pad on the semiconductor wafer, forming a re-wiring layer on the pad, and forming the first metal post on the re-wiring layer, and the step of preparing the semiconductor chip may include the steps of forming a pad within the semiconductor chip, forming a re-wiring layer on the pad, and forming the second metal post on the re-wiring layer.

A method for manufacturing a semiconductor device can include the steps of preparing a semiconductor wafer wherein a first metal ball for taking out an electrode is formed on a surface of each of a plurality of chip regions, preparing a semiconductor chip wherein a second metal ball for taking out an electrode is formed on a surface thereof. Further, the method can include disposing the semiconductor chip on each of the chip regions of the semiconductor wafer through an adhesive layer, sealing the semiconductor wafer, the first metal ball, the semiconductor chip and the second metal ball with a resin, and removing the resin by a specified amount to expose surfaces of the respective first metal ball and second metal ball.

By the method for manufacturing a semiconductor device describe above, external terminals are formed with the first and second metal balls, and therefore processes that strictly control formation of metal posts and thickness of the sealing resin are not required. Accordingly, the process is simplified, the throughput can be improved, and the manufacturing costs can be reduced.

Also, the method for manufacturing a semiconductor device in accordance with the present invention may further include the step of, after the step of exposing, dividing the semiconductor wafer into individual chips.

Also, in the method for manufacturing a semiconductor device in accordance with the present invention, the step of preparing the semiconductor wafer may include the steps of forming a pad on the semiconductor wafer, forming a re-wiring layer on the pad, and forming the first metal ball on the re-wiring layer, and the step of preparing the semiconductor chip may include the steps of forming a pad within the semiconductor chip, forming a re-wiring layer on the pad, and forming the second metal ball on the re-wiring layer.

### BRIEF DESCRIPTION OF THE DRAWINGS

The invention will be described with reference to the accompanying drawings, wherein like numerals reference like elements, and wherein:

FIG. 1 schematically shows a cross-sectional view of a semiconductor device in accordance with a first embodiment of the present invention;

FIG. 2 shows a partially enlarged cross-sectional view of a metal post region shown in FIG. 1;

FIGS. 3(A)-(E) show in cross section a method for manufacturing a metal post shown in FIG. 2;

FIGS. 4(A)-4(D) show in cross section a method for manufacturing the semiconductor device shown in FIG. 1;

FIGS. 5(A)-5(D) show in cross section a method for manufacturing a semiconductor device in accordance with a second embodiment of the present invention;

FIG. 6 schematically shows a cross-sectional view of a semiconductor device in accordance with a third embodiment of the present invention;

FIG. 7 shows a partially enlarged cross-sectional view of a metal post region shown in FIG. 6;

FIGS. 8(A)-8(E) show in cross section a method for manufacturing the metal post shown in FIG. 7;

FIGS. 9(A)-9(D) show in cross section a method for manufacturing the semiconductor device shown in FIG. 6;

FIG. 10 schematically shows a cross-sectional view of a semiconductor device in accordance with a fourth embodiment of the present invention;

FIG. 11 schematically shows a cross-sectional view of a semiconductor device in accordance with a fifth embodiment of the present invention; and

FIG. 12 schematically shows a cross-sectional view of an example of a conventional semiconductor device.

### DETAILED DESCRIPTION OF PREFERRED EMBODIMENTS

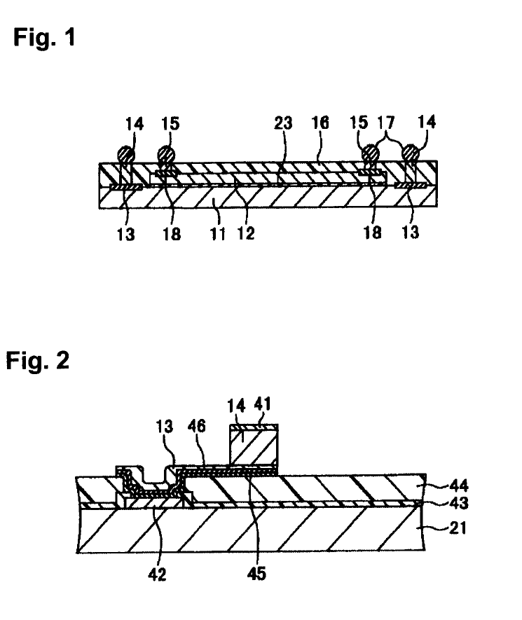

Embodiments of the present invention will be described below with reference to the accompanying drawings. FIG. 1 schematically shows a cross-sectional view of a semiconductor device in accordance with a first embodiment of the present invention.

As shown in FIG. 1, a second semiconductor chip 12 is bonded to a central area of and on a first semiconductor chip 11 through a dielectric bonding layer 23. The dielectric bonding layer 23 electrically insulates the second semiconductor chip 12 from the first semiconductor chip 11, and adheres a surface (active surface) of the first semiconductor chip 11 and a rear surface of the second semiconductor chip.

Pads (not shown) for taking out electrodes are disposed along an outer circumference of an active surface of the first semiconductor chip 11, and re-wiring layers 13 are disposed on the pads for taking out electrodes. Metal posts 14 are formed on the re-wiring layers 13. Also, pads (not shown) for taking out electrodes are disposed along an outer circumference of an active surface of the second semiconductor chip 12, and re-wiring layers 18 are disposed on the pads for taking out electrodes. Metal posts 15 are formed on the re-wiring layers 18. The pads and re-wiring layers are laid out in the chip in advance such that the metal posts 14 and 15 do not interfere with one another.

The active surface of the first semiconductor chip 11, the re-wiring layers 13, the metal posts 14, the active surface of the second semiconductor chip 12, the re-wiring layers 18 and the metal posts 15 are covered with a sealing resin 16 and molded. Upper surfaces of the metal posts 14 and 15 are exposed through the sealing resin 16. Mounting external terminals 17, such as solder balls, are formed on the respective upper surfaces of the exposed metal posts 14 and 15 depending on the requirements, which form a wire-less stacked package. It is noted that the mounting external terminals 17 may not necessarily be required, and a semiconductor device can also be provided without mounting external terminals 17. Also, wirings are patterned according to circuits of a semiconductor device on a printed circuit board of an electronic apparatus on which the semiconductor device is mounted, and the semiconductor device is mounted at a required position on the printed circuit board in a mounting process.

FIG. 2 shows a partially enlarged cross-sectional view of a metal post region shown in FIG. 1. Pads 42 for taking out electrodes are formed on an active surface (surface) of a semiconductor wafer 21. The pads 42 for taking out electrodes are connected to various metal wirings (not shown) composed of Al, Cu or the like within the semiconductor wafer 21, and the various metal wirings are electrically connected to semiconductor elements, such as MOS transistors, through interlayer dielectric films (not shown). The semiconductor elements are formed within the semiconductor wafer 21.

A final protection dielectric layer 43 composed of a silicon oxide film or a silicon nitride film is formed on the entire surface of the semiconductor wafer 21 including the pads 42 for taking out electrodes. Opening sections are formed in the final protection dielectric layer 43 at locations above the pads 42 for taking out electrodes. A polyimide layer 44 having a thickness of, for example, about several ten-100 μm is formed on the final protection dielectric layer 43. The polyimide layer 44 is a layer that alleviates stresses on the semiconductor elements. Opening sections are formed in the polyimide layer 44, and these opening sections open to the opening sections in the final protection dielectric layer 43.

A cohesion layer 45 is formed within the opening sections and on the polyimide layer 44. The cohesion layer 45 is a layer that is composed of a high-melting point metal, such as Ti, W, TiW, Cr, Ni, TiCu, Pt or the like, or an alloy of these metals, or a nitride film of these metal. A Cu seed layer 46 is formed on the cohesion layer 45. As the Cu seed layer 46, a layer composed of Ni, Ag or Au or an alloy of these metals may be used, in addition to Cu.

A re-wiring layer 13 having a thickness of about several-several ten μm is formed on the Cu seed layer 46. The re-wiring layer 13 is formed by selectively plating Cu. A metal post 14 is formed on one end of the re-wiring layer 13. The metal post 14 is formed by selectively plating Cu or the like. A heterogeneous metal cap 41 is formed on the metal post 14 to prevent oxidation depending on the requirements. The heterogeneous metal cap 41 is formed from a material of a type different from that of the metal post, for example, Ni, Au or Pt. The metal post 14 is electrically connected to the pad 42 for taking out an electrode through the re-wiring layer 13.

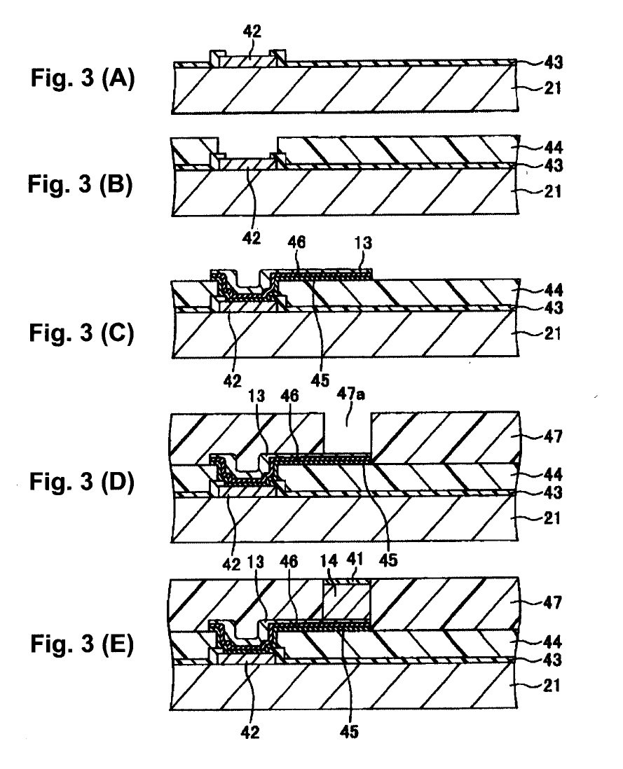

Next, a method for manufacturing the metal post shown in FIG. 2 is described. FIGS. 3(A)-(E) show in cross section a method for manufacturing the metal post shown in FIG. 2.

First, as shown in FIG. 3(A), a semiconductor wafer 21 is prepared. Semiconductor elements, such as MOS transistors, a variety of metal wirings electrically connected to the semiconductor elements, and interlayer dielectric layers are formed within the semiconductor wafer 21. Next, pads 42 for taking out electrodes are formed on one ends of the variety of metal wirings. Then, a final protection dielectric layer 43 that is composed of a silicon oxide film or a silicon nitride film is formed on the entire surface including the pads 42 by a CVD (Chemical Vapor Deposition) method.

Next, a photoresist film (not shown) is coated on the final protection dielectric layer 43, and the photoresist film is exposed to light and developed, whereby a resist pattern is formed on the final protection dielectric layer 43. Next, the final protection dielectric layer 43 is etched using the resist pattern as a mask. As a result, opening sections are formed in the final protection dielectric layer 43 at locations above the pads 42 for taking out electrodes, and surfaces of the pads 42 are exposed through the opening sections.

Next, as shown in FIG. 3(B), a polyimide layer 44 having a thickness of, for example, about several ten-100 μm is coated on the final protection dielectric layer 43. Then, a photoresist film (not shown) is coated on the polyimide layer 44, and the photoresist film is exposed to light and developed, whereby a resist pattern is formed on the polyimide layer 44. Next, the polyimide layer 44 is etched using the resist pattern as a mask, whereby opening sections are formed in the polyimide layer 44 at locations over the pads 42 for taking out electrodes, and surfaces of the pads 42 are exposed through the opening sections. It is noted that, in this process, photosensitive polyimide may be used to directly form patterns with opening sections, to thereby simplify the process including photoresist coating, etching and removing steps.

Then, as shown in FIG. 3(C), a cohesion layer 45 composed of a high-melting point metal is formed by a sputtering method inside the opening sections and on the polyimide layer 44. Next, a Cu seed layer 46 is formed on the cohesion layer 45 by a sputtering method. Next, a Cu layer having a thickness of about several-several ten μm is formed on the Cu seed layer 46 by a selective plating method. Then, the Cu seed layer 46 and the cohesion layer 45 are selectively etched using the Cu layer as a mask. As a result, a re-wiring layer 13 is formed over the polyimide layer 44 through the cohesion layer 45, and one end of the re-wiring layer 13 is electrically connected to the pad 42 for taking out an electrode.

Next, as shown in FIG. 3(D), a photoresist film is coated on the entire surface including the re-wiring layer 13, and the photoresist film is exposed to light and developed, whereby a resist pattern 47 having an opening section 47a located above another end of the re-wiring layer 13 is formed on the polyimide layer 44.

Then, as shown in FIG. 3(E), a metal post 14 composed of a Cu plated film is formed on the re-wiring layer 13 inside the opening section 47a by a selective plating, using the resist pattern 47 as a mask. It is noted that control of the thickness and size of the metal post composed of a Cu plated film is relatively easy. Next, a heterogeneous metal cap 41 composed of Ni or the like is formed on the metal post 14 by a plating method. Then, the resist pattern 47 is removed, to form the semiconductor device shown in FIG. 2. The semiconductor device has so far been manufactured by a wafer process.

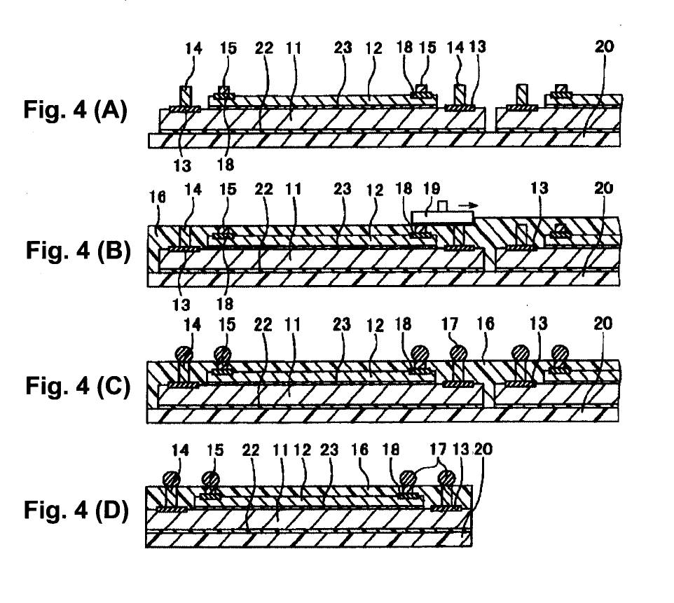

Next, a method for manufacturing the semiconductor device shown in FIG. 1 will be described. FIGS. 4(A)-4(D) show in cross section a method for manufacturing the semiconductor device shown in FIG. 1.

First, as shown in FIG. 4(A), a plate-like supporting member 20 on which a plurality of chips can be disposed is prepared, and a first semiconductor chip 11 and a second semiconductor chip 12 are prepared. It should be understood that the supporting member 20 is not limited to a resin, a metal or a ceramic, and a member formed form any of various materials can be used as long as the reinforcing property and heat resistance property in a process of stacking semiconductor chips are secured. For example, polyimide or a thin film steel material may preferably be used. Also, the first and second semiconductor chips 11 and 12 are provided by dicing and dividing the semiconductor wafer, which has been processed up to a state in which the metal posts 14 are formed as shown in FIG. 3, into individual chips.

Then, a plurality of first semiconductor chips 11 are disposed on the supporting member 20 through a bonding layer 22, such as a thermocompression bonding sheet. In other words, rear faces of the first semiconductor chips 11 are bonded to a surface of the supporting member 20 by the bonding layer 22. In this instance, the supporting member 20 and the first semiconductor chips 11 are aligned with one another, using mounting identification marks formed on the supporting member 20 as references.

Then, a plurality of second semiconductor chips 12 are disposed on central sections of active surfaces of the respective first semiconductor chips 11 through bonding layers 23 such as thermocompression sheets. In other words, rear surfaces of the second semiconductor chips 12 are bonded to active surfaces (surfaces) of the first semiconductor chips 11 by the bonding layers 23. In this instance, the first semiconductor chips 11 and the second semiconductor chips 12 are aligned with one another, using mounting identification marks as references. It is noted that the second semiconductor chips 12 that are used have been ground to have a thickness (a thickness of the chip including the metal posts 15) that is thinner than the height of the metal posts 14 of the first semiconductor chips 11.

Then, as shown in FIG. 4(B), the surface of the supporting member 20, the first semiconductor chips 11, the re-wiring layers 13, the metal posts 14, the second semiconductor chips 12, the re-wiring layers 18, and the metal posts 15 are covered with a sealing resin 16, such as an epoxy resin and molded by a molding apparatus. Then, the sealing resin 16 is ground by a grinder 19 by a required amount. The required amount can be an amount to be ground to the extent that head sections (upper sections) of the metal posts 14 and 15 are exposed.

Next, as shown in FIG. 4(C), the exposed portions of the metal posts 14 and 15 are coated with flux (not shown), and then solder balls are mounted on designated ones of the metal posts 14 and 15 by an automatic mounting apparatus. Next, the metal posts 14 and 15 and the solder balls are subject to a heat treatment at about 170-200° C. As a result, the solder balls are fused and bonded onto the metal posts 14 and 15 to thereby form mounting external terminals 17. preferably be those used for a BGA (Ball Grid Array), having a diameter of 150-300 μm, and formed from a material containing Pb/Sn by 60-70 wt %. Also, the size of each of the mounting external terminals 17 can be appropriately selected depending on the usage. Ag/Sn containing solder, or Pb-less material containing Cu or Bi may also be used as the solder. Also, it should be understood that the mounting external terminals 17 are not limited to solder balls. Instead of mounting solder balls, mounting external terminals that may be formed by a printing method, a plating method or a metal jet method are also applicable without departing from the spirit and scope of the present invention.

Then, as shown in FIG. 4(D), the resin 16 and the supporting member 20 are cut by a dicing saw or a laser beam to provide individual CSP type semiconductor devices, each having the second semiconductor chip stacked in layer on the first semiconductor chip.

Next, the supporting member 20 and the bonding layer 22 may be removed depending on the specification requirements, such as, according to a specified thickness of the CSP type semiconductor devices. In a manner described above, a wire-less stacked level CSP type semiconductor device shown in FIG. 1 is manufactured. The CSP type semiconductor devices are mounted on a variety of mother boards formed from polyimide for mobile equipment and the like. It is noted that the electrical properties of the CSP type semiconductor devices may preferably be examined in a step before or after they are cut and divided into single units.

In accordance with the first embodiment of the present invention, the second semiconductor chip 12 is disposed in a central area of and on the first semiconductor chip 11 that has the metal posts 14 formed thereon through the dielectric bonding layer 23, the active surface of the first semiconductor chip 11 and the second semiconductor chip 12 are covered and sealed by a resin, and mounting external terminals are mounted on the metal posts 14 and 15 of the respective chips 11 and 12 exposing through the resin. By this, wire-less stacked-level CSP type semiconductor devices can be manufactured at low costs. Accordingly, further miniaturization can be achieved compared to the conventional devices, and the yield and reliability can be improved. Therefore, semiconductor devices and electronic apparatuses on which the semiconductor devices are mounted can be further miniaturized, and their mounting density can be improved.

Also, in the first embodiment, the metal posts are formed from plated films, and the mounting external terminals are formed with solder balls. Accordingly, the size and height of the metal posts and mounting external terminals can be readily changed. As a result, second semiconductor chips 12 with various different thickness can be stacked in layer, and thus wire-less chip-stacked type CSPs can be manufactured without being restricted by the thickness of the chips.

It is noted that single pieces of the first and second semiconductor chips may be stacked in layer, sealed with a resin, ground and provided with external terminals independently from others. However, this only yields a low productively. Therefore, it would be effective if a plurality of devices are formed on a supporting member like the embodiment described above, and cut in a final step.

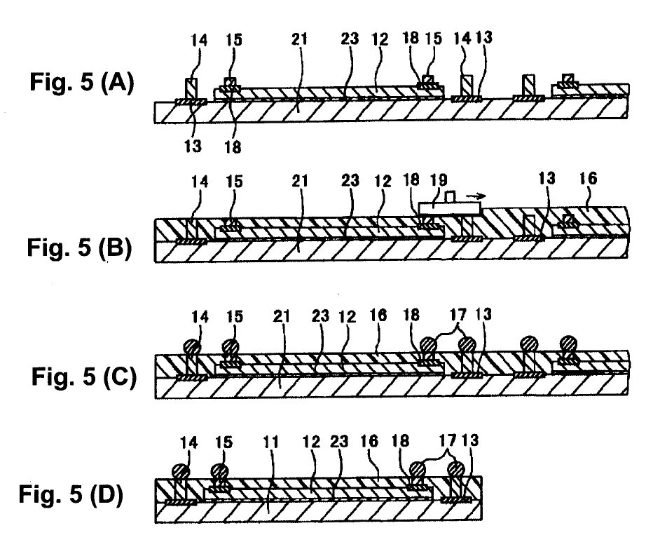

FIGS. 5(A)-5(D) show in cross section a method for manufacturing a semiconductor device in accordance with a second embodiment of the present invention, and the same elements as those shown in FIG. 4 are indicated with the reference numbers.

A semiconductor wafer 21 as indicated in FIG. 2, which has been processed to a state where re-wiring layers 13 and metal posts 14 are formed by a wafer process, is prepared, and second semiconductor chips 12 are prepared. Here, the second semiconductor chips 12 are individual chips obtained by dicing and dividing the semiconductor wafer that has been processed to a state where metal posts are formed as indicated in FIG. 3.

Then, a plurality of the second semiconductor chips 12 are disposed on the semiconductor wafer 21 through a dielectric bonding layer 23, such as a thermocompression sheet. In other words, rear surfaces of the second semiconductor chips 12 are bonded to central areas in respective chip regions of the wafer 21 by the dielectric bonding layer 23. In this instance, the semiconductor wafer 21 and the second semiconductor chips 12 are aligned with one another, using mounting identification marks formed on the wafer 21 as references. These mounting identification marks are patterned in scribe regions or the like all at once in a photo-etching process in the wafer process. It is noted that the second semiconductor chips 12 that are used have been ground to have a thickness (a thickness of the chip including the metal posts 15) that is thinner than the height of the metal posts 14 of the semiconductor wafer 21.

Then, as shown in FIG. 5(B), the active surface (surface) of the semiconductor wafer 21, the re-wiring layers 13, the metal posts 14, the second semiconductor chips 12, the re-wiring layers 18, and the metal posts 15 are covered with a sealing resin 16 such as an epoxy resin and molded by a molding apparatus. Then, the sealing resin 16 is ground by a grinder 19 by a required amount. The required amount means an amount to be ground to the extent that head sections (upper sections) of the metal posts 14 and 15 are exposed.

Here, the grinder 19 is used to grind the sealing resin 16, but it should be understood that the sealing resin 16 can be ground by another method without being limited to this method. For example, the entire upper surface of the wafer may be ground together by a mechanical polishing method, or etched back by a dry etcher using oxygen, CF4 or NF3, or a mixture of these gases.

Next, as shown in FIG. 5(C), the exposed portions of the metal posts 14 and 15 are coated with flux (not shown), and then solder balls are mounted on designated ones of the metal posts 14 and 15 by an automatic mounting apparatus. Next, the metal posts 14 and 15 and the solder balls are subject to a heat treatment at about 170-200° C. As a result, the solder balls are fused and bonded onto the metal posts 14 and 15 to thereby form mounting external terminals 17.

The solder balls that become the mounting external terminals 17 may preferably be those for a BGA, like the first embodiment. The size of each of the mounting external terminals 17 can be appropriately selected depending on the usage. Ag/Sn containing solder, or Pb-less material containing Cu or Bi may also be used as the solder. Also, the mounting external terminals 17 are not limited to solder balls. Instead of mounting solder balls, mounting external terminals that may be formed by a printing method, a plating method or a metal jet method are also applicable.

Then, as shown in FIG. 5(D), the resin 16 and the semiconductor wafer 21 are cut by a dicing saw or a laser beam to provide individual CSP type semiconductor devices, each having the second semiconductor chip stacked in layer on the first semiconductor chip. As a result, the wafer is divided into individual chips, which become the first semiconductor chips 11 in the device configuration. In this manner, wire-less stacked level CSP type semiconductor devices are manufactured.

Next, the CSP type semiconductor devices are mounted on a variety of mother boards formed from polyimide or the like for mobile equipment and the like. It is noted that the electrical properties of the CSP type semiconductor devices may preferably be examined in a step before or after they are divided and cut into single units.

The second embodiment also creates effects similar to those of the first embodiment.

Further, in the second embodiment, the second semiconductor chips 12 are stacked in a layer on the wafer 21 before it is divided into the first semiconductor chips 11, which are then sealed with resin at wafer level, the mounting external terminals 17 are provided on the metal posts 14 and 15, and then divided into individual units at CSP level. As a result, since the semiconductor wafer 21 plays a role of the supporting member of the first embodiment during the assembly process, a supporting member is not required, which can eliminate materials including the bonding layer and the number of process steps, compared to the first embodiment. Consequently, much thinner and smaller stacked level CSP type semiconductor devices can be obtained at lower costs.

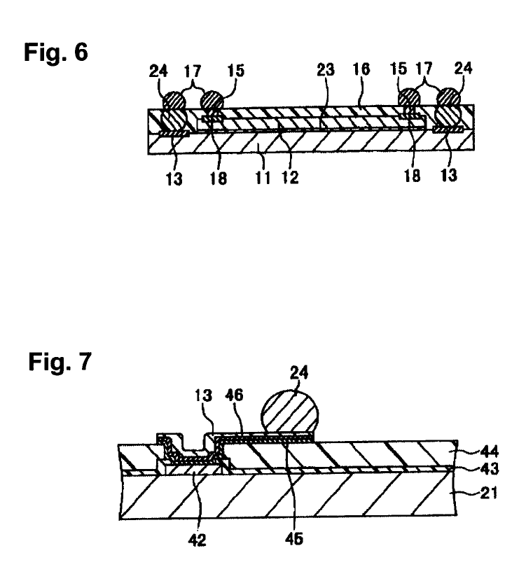

FIG. 6 schematically shows a cross-sectional view of a semiconductor device in accordance with a third embodiment of the present invention, wherein the same elements as those shown in FIG. 1 are indicated by the same reference numbers. Metal posts 24 formed from solder balls are disposed on re-wiring layers 13 on a first semiconductor chip 11. Other parts are structured in a similar manner as those shown in FIG. 1, and therefore their description is omitted.

FIG. 7 shows a partially enlarged cross-sectional view of a metal post region shown in FIG. 6, wherein the same parts as those shown in FIG. 2 are indicated by the same reference numbers. A metal post 24 formed from a solder ball is formed on one end of a re-wiring layer 13. Other parts are structured in a similar manner as those shown in FIG. 2, and therefore their description is omitted.

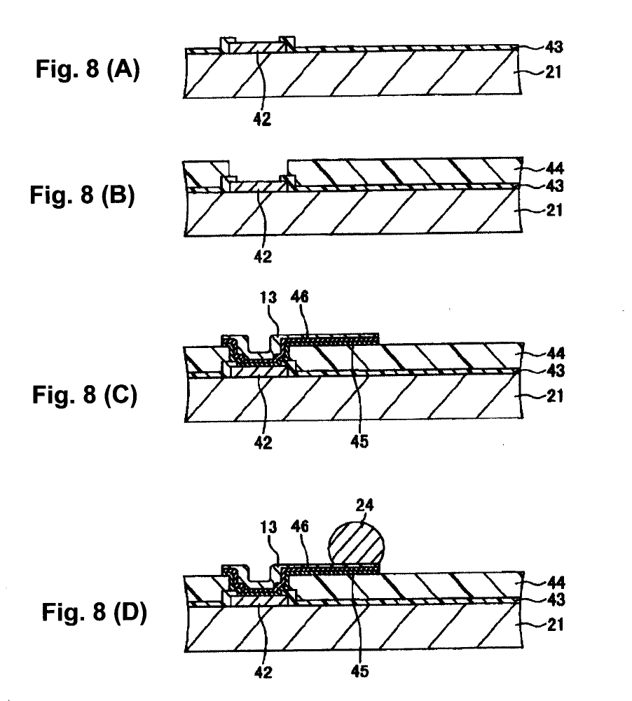

Next, a method for manufacturing the metal post shown in FIG. 7 will be described. FIGS. 8(A)-8(E) show in cross section a method for manufacturing the metal post shown in FIG. 7. First, as shown in FIG. 8(A), a semiconductor wafer 21 is prepared. Semiconductor elements, such as MOS transistors, a variety of metal wirings electrically connected to the semiconductor elements, and interlayer dielectric layers are formed within the semiconductor wafer 21. Next, pads 42 for taking out electrodes are formed on one ends of the variety of metal wirings. Next, a final protection dielectric layer 43 that is composed of a silicon oxide film or a silicon nitride film is formed on the entire surface including the pads 42 by a CVD method.

Next, the final protection dielectric layer 43 is patterned such that opening sections are formed in the final protection dielectric layer 43 at locations above the pads 42 for taking out electrodes, and surfaces of the pads 42 are exposed through the opening sections.

Next, as shown in FIG. 8(B), a polyimide layer 44 having a thickness of, for example, about several ten-100 μm is coated on the final protection dielectric layer 43. Next, the polyimide layer 44 is patterned such that opening sections are formed in the polyimide layer 44 at locations over the pads 42 for taking out electrodes, and surfaces of the pads 42 are exposed through the opening sections.

Then, as shown in FIG. 8(C), a cohesion layer 45 composed of a high-melting point metal is formed by a sputtering method inside the opening sections and on the polyimide layer 44. Next, a Cu seed layer 46 is formed on the cohesion layer 45 by a sputtering method. Next, a Cu layer having a thickness of about several-several ten μm is formed on the Cu seed layer 46 by a selective plating method. Then, the Cu seed layer 46 and the cohesion layer 45 are selectively etched using the Cu layer as a mask. As a result, a re-wiring layer 13 is formed over the polyimide layer 44 through the cohesion layer 45, and one end of the re-wiring layer 13 is electrically connected to the pad 42 for taking out an electrode.

Next, as shown in FIG. 8(D), one end portions of the re-wiring layers 13 are coated with flux (not shown), and then solder balls having a diameter of about 300 μm and composed of Pb/Sn are mounted on designated ones of the re-wiring layers 13 by an automatic mounting apparatus. Next, the re-wiring layers 13 and the solder balls are subject to a heat treatment at about 170-200° C. As a result, the solder balls are fused and bonded onto the re-wiring layers 13 to thereby form metal posts 24.

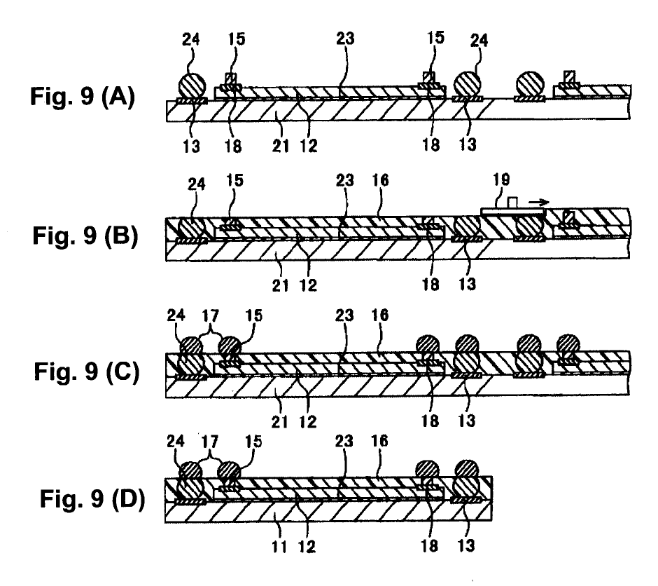

Next, a method for manufacturing the semiconductor device shown in FIG. 6 will be described. FIGS. 9(A)-9(D) show in cross section a method for manufacturing the semiconductor device shown in FIG. 6.

First, as shown in FIG. 9(A), a semiconductor wafer 21 as indicated in FIG. 7, which has been processed to a state where re-wiring layers 13 and metal posts 14 are formed by a wafer process, is prepared, and second semiconductor chips 12 are prepared. Here, the second semiconductor chips 12 are individual chips obtained by dividing the semiconductor wafer that has been processed to a state where metal posts are formed as indicated in FIG. 2.

Then, a plurality of the second semiconductor chips 12 are disposed on the semiconductor wafer 21 through a dielectric bonding layer 23, such as a thermocompression sheet. In other words, rear surfaces of the second semiconductor chips 12 are bonded to central areas in respective chip regions of the wafer 21 by the dielectric bonding layer 23. In this instance, the semiconductor wafer 21 and the second semiconductor chips 12 are aligned with one another, using mounting identification marks formed on the wafer 21 as references. These mounting identification marks are patterned in scribe regions or the like all at once in a photo-etching process in the wafer process.

It is noted that the embodiment above uses the semiconductor wafer 21 on which the metal posts 24 formed from solder balls are mounted in advance. However, without being limited to this embodiment, the following is also possible. A semiconductor wafer which does not have metal posts 24 mounted thereon may be prepared, second semiconductor chips 12 may be disposed in layer on the wafer, then solder balls for metal posts are mounted on re-wiring layers of the wafer, and then a heat treatment is conducted to fuse and bond the re-wiring layers and the solder balls.

Then, as shown in FIG. 9(B), the active surface (surface) of the semiconductor wafer 21, the re-wiring layers 13, the metal posts 24, the second semiconductor chips 12, the re-wiring layers 18, and the metal posts 15 are covered with a sealing resin 16 such as an epoxy resin and molded by a molding apparatus. Then, the sealing resin 16 is ground by a grinder 19 by a required amount. The required amount can be an amount to be ground to the extent that head sections (upper sections) of the metal posts 24 and 15 are exposed. By forming the metal posts with solder balls, the metal posts can be relatively quickly ground when the resin is ground by the grinder, such that stresses on the metal posts can be reduced.

Here, the grinder 19 is used to grind the sealing resin 16, but it should be understood that the sealing resin 16 can be ground by another method without being limited to this method. For example, the entire upper surface of the wafer may be ground together by a mechanical polishing method, or etched back by a dry etcher using oxygen, CF4 or NF3, or a mixture of these gases.

Next, as shown in FIG. 9(C), the exposed portions of the metal posts 24 and 15 are coated with flux (not shown), and then solder balls are mounted on designated ones of the metal posts 24 and 15 by an automatic mounting apparatus. Next, the metal posts 24 and 15 and the solder balls are subject to a heat treatment at about 170-200° C. As a result, the solder balls are fused and bonded onto the metal posts 24 and 15 to thereby form mounting external terminals 17.

The solder balls that become the mounting external terminals 17 may preferably be those for a BGA, like the first embodiment. The size of each of the mounting external terminals 17 can be appropriately selected depending on the usage. Ag/Sn containing solder, Pb-less material containing Cu or Bi, Cu, Ni, another high-melting point metal or an alloy of these metals may also be used as the solder. Also, the mounting external terminals 17 are not limited to solder balls. Instead of mounting solder balls, mounting external terminals that may be formed by a printing method, a plating method or a metal jet method are also applicable.

Then, as shown in FIG. 9(D), the resin 16 and the semiconductor wafer 21 are cut by a dicing saw or a laser beam to provide individual CSP type semiconductor devices, each having the second semiconductor chip stacked in layer on the first semiconductor chip. As a result, the wafer is divided into individual chips, which become the first semiconductor chips 11 in the device configuration. In this manner, wire-less stacked level CSP type semiconductor devices are manufactured.

The third embodiment also creates effects similar to those of the second embodiment.

Also, in the third embodiment, the metal posts 24 are formed with mounting metal balls on which solder balls are mounted. This is advantageous as large metal posts can be formed at low costs and in a shorter process, compared to the case in which metal posts are formed with plating. Accordingly, by forming the metal posts 24 having a greater height with large solder balls, the thickness of the second semiconductor chips 12 does not need to be extremely thin. This makes it easier to work the second semiconductor chips 12 due to their improved strength.

Also, the third embodiment provides a structure in which areas around the metal posts 24 formed from mounting metal balls are wrapped and pressed down by the sealing resin 16. For this reason, when this CSP type semiconductor device is mounted on a printed circuit board and on a flexible circuit board in particular, the durability and strength thereof against stresses applied to the metal posts 24 are improved. As a result, occurrence of defective modes, such as falls of metal posts, can be reduced, and the reliability of the devices can be improved and mounting yield can also be improved.

Also, the third embodiment provides a structure in which external terminals formed from metal balls are directly mounted on the re-wiring layers of the semiconductor chips. This enables manufacture of CSP type semiconductor devices suitable for mass production at low costs.

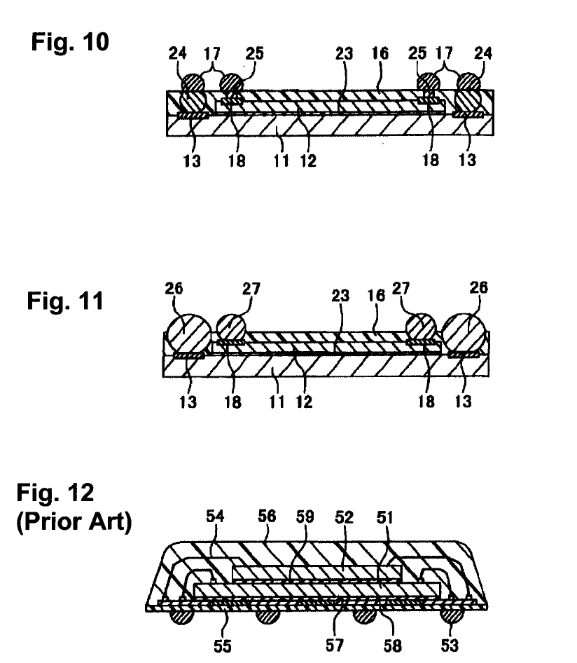

FIG. 10 schematically shows a cross-sectional view of a semiconductor device in accordance with a fourth embodiment of the present invention, wherein the same elements as those shown in FIG. 6 are indicated by the same reference numbers. Metal posts 25 formed from solder balls are disposed on re-wiring layers 18 on a second semiconductor chip 12. Other parts are structured in a similar manner as those shown in FIG. 6, and therefore their description is omitted.

Next, a method for manufacturing the semiconductor device shown in FIG. 10 will be described.

First, a semiconductor wafer 21 indicated in FIG. 7, which has been processed to a state in which re-wiring layers 13 and metal posts formed from solder balls having a diameter of 350 μm are formed by a wafer process, is prepared, and second semiconductor chips 12 are prepared. Here, the second semiconductor chips 12 are individual chips provided by dicing and dividing a semiconductor wafer that has been processed to a state in which metal posts 25 formed from solder balls having a diameter of 150 μm are formed.

Then, in a similar manner as the third embodiment, a plurality of the second semiconductor chips 12 are disposed on the semiconductor wafer through a dielectric bonding layer 23 such as a thermocompression sheet.

It is noted that this embodiment uses the semiconductor wafer 21 on which the metal posts 24 formed from solder balls are mounted in advance and the second semiconductor chips 12 on which metal posts 25 formed from solder balls are mounted in advance. However, without being limited to this embodiment, the following is also possible. A semiconductor wafer and second semiconductor chips which do not have metal posts 24 or 25 mounted thereon may be prepared, the second semiconductor chips may be disposed in layer on the wafer, then solder balls for metal posts are mounted on re-wiring layers of the respective wafer and the second semiconductor chips, and then a heat treatment is conducted to fuse and bond the re-wiring layers and the solder balls. Therefore, more flexible process flows can be constructed.

Then, the active surface (surface) of the semiconductor wafer, the re-wiring layers 13, the metal posts 24, the second semiconductor chips 12, the re-wiring layers 18, and the metal posts 25 are covered with a sealing resin 16 such as an epoxy resin and molded by a molding apparatus. Then, the sealing resin 16 is ground by a grinder 19 by a required amount. The required amount means an amount to be ground to the extent that head sections (upper sections) of the metal posts 24 and 25 are exposed.

Here, the grinder 19 is used to grind the sealing resin 16, but can be ground by another method without being limited to this method.

Next, the exposed portions of the metal posts 24 and 25 are coated with flux (not shown), and then solder balls are mounted on designated ones of the metal posts 24 and 25 by an automatic mounting apparatus. Next, the metal posts 24 and 25 and the solder balls are heat treated at about 170-200° C. As a result, the solder balls are fused and bonded onto the metal posts 24 and 25 to thereby form mounting external terminals 17.

The solder balls that become the mounting external terminals 17 may preferably be those for a BGA, like the first embodiment. The size of each of the mounting external terminals 17 can be appropriately selected depending on the usage. Ag/Sn containing solder, Pb-less material containing Cu or Bi, Cu, Ni, another high-melting point metal or an alloy of these metals may also be used as the solder. Also, it should be understood that the mounting external terminals 17 are not limited to solder balls. Instead of mounting solder balls, mounting external terminals that may be formed by a printing method, a plating method or a metal jet method are also applicable.

Then, the resin 16 and the semiconductor wafer 21 are cut by a dicing saw or a laser beam to provide individual CSP type semiconductor devices, each having the second semiconductor chip stacked in layer on the first semiconductor chip. As a result, the wafer is divided into individual chips as shown in FIG. 10, which become the first semiconductor chips 11 in the device configuration. In this manner, wire-less stacked level CSP type semiconductor devices are manufactured.

The fourth embodiment also creates effects similar to those of the third embodiment. Moreover, since all of the metal posts 24 and 25 have a generally perfect spherical form, occurrence of defects such as falls of posts can be further reduced when they are mounted on printed circuit boards, compared to the third embodiment.

Also, in the fourth embodiment, all the metal posts 24 and 25 are formed with solder balls, such that steps of forming a thick Cu layer by plating at the time of forming the metal posts, forming a cap layer and conducting a photolithography step are not required. As a result, the throughput is improved and the costs can be reduced.

FIG. 11 schematically shows a cross-sectional view of a semiconductor device in accordance with a fifth embodiment of the present invention, in which the same elements as those shown in FIG. 10 are indicated by the same reference numbers.

Mounting external terminals 26 are disposed on re-wiring layers 13 on the active surface (surface) of a first semiconductor chip 11. Mounting external terminals 27, which are smaller in size than the mounting external terminals 26, are disposed on re-wiring layers 18 on the active surface (surface) of a second semiconductor chip 12. The surface of the first semiconductor chip 11, circumferential areas of the mounting external terminals 26, the second semiconductor chip 12 and circumferential areas of the mounting external terminals 27 are covered by a sealing resin 16. Head sections (upper sections) of the respective mounting external terminals 26 and 27 are exposed through the sealing resin 16. Other parts are structured in a similar manner as those shown in FIG. 10, and therefore their description is omitted.

Next, a method for manufacturing the semiconductor device shown in FIG. 11 will be described.

First, a semiconductor wafer, which has been processed to a state in which re-wiring layers 13 are formed by a wafer process, is prepared, and second semiconductor chips 12 are prepared. Here, the second semiconductor chips 12 are individual chips provided by dicing and dividing a semiconductor wafer that has been processed to a state in which re-wiring layers 18 are formed.

Then, a plurality of the second semiconductor chips 12 are disposed on the semiconductor wafer through a dielectric bonding layer 23, such as a thermocompression sheet. In other words, rear surfaces of the second semiconductor chips 12 are bonded to central areas in respective chip regions of the wafer by the dielectric bonding layer 23. In this instance, the semiconductor wafer and the second semiconductor chips 12 are aligned with one another, using mounting identification marks formed on the wafer as references. These mounting identification marks are patterned in scribe regions or the like all at once in a photo-etching process in the wafer process.

Then, flux (not shown) is spin-coated or sprayed on the re-wiring layers 13 and 18, and then solder balls are mounted on designated ones of the re-wiring layers 13 and 18 by an automatic mounting apparatus. The size of the solder balls to be mounted in this instance may preferably be 250-350 μm in diameter on the re-wiring layers 13 of the semiconductor wafer, and 100-200 μm in diameter on the re-wiring layers 18 of the second semiconductor chips 12. The reason for this is to adjust the thickness of the second semiconductor chips 12. Next, the re-wiring layers 13 and 18, and the solder balls are subject to a heat treatment at about 170-200° C. As a result, the solder balls are fused and bonded onto the re-wiring layers 13 to thereby form metal posts 26, and the solder balls are fused and bonded onto the re-wiring layers 18 to thereby form metal posts 27.

Then, the active surface (surface) of the semiconductor wafer, the re-wiring layers 13, the metal posts 26, the second semiconductor chips 12, the re-wiring layers 18, and the metal posts 27 are coated and covered with a sealing resin 16, such as an epoxy resin to a specified thickness by a molding apparatus. Then, the sealing resin 16 is etched back by a plasma apparatus, using plasma generated with an oxygen mixed gas. As a result, the surfaces of the external terminals 26 and 27 are exposed through the sealing resin 16.

Next, the electrical property is examined, and parts numbers and the like are printed. Then, the resin 16 and the semiconductor wafer are cut by a dicing saw or a laser beam to provide individual CSP type semiconductor devices, each having the second semiconductor chip stacked in layer on the first semiconductor chip. As a result, the wafer is divided into individual chips, which become the first semiconductor chips 11 in the device configuration. In this manner, wire-less stacked level CSP type semiconductor devices are manufactured. Then, the CSP type semiconductor devices are mounted on printed circuit boards of electrical apparatuses or the like.

The fifth embodiment provides effects similar to those of the fourth embodiment.

Also, since the fifth embodiment does not require steps for strictly controlling formation of metal posts or the thickness of sealing resin, the process is simplified, the throughput can be further improved, and the manufacturing costs can be further reduced.

It is noted that, in the fifth embodiment, solder balls that become external terminals are not mounted at the wafer level. Instead, after the element forming process (wafer process) is completed, the second semiconductor chips 12 are stacked in layer on central areas of respective first semiconductor chip regions of the semiconductor wafer, and then solder balls are mounted. However, without being limited to this method, the following is also possible. Solder balls that are to become external terminals may be mounted at the wafer level during an element forming process, then second semiconductor chips 12 may be stacked in layer on the wafer that is to become first semiconductor chips 11, and then a molding process may be conducted.

Also, it should be understood that the present invention is not limited to the first through fifth embodiments, and can be modified and implemented in many ways. For example, in the embodiments described above, a two-layer chip stacked structure is provided, in which a second semiconductor chip is stacked in layer on a first semiconductor chip, but a chip stacked layer structure can be formed with three or more layers. Also, the CSP type semiconductor devices described above are applicable to a variety of LSIs such as memories and logics.

Furthermore, in the embodiments described above, the sealing resin is ground and mounting external terminals are formed before a cutting step. However, mounting external terminals can be formed after individual chip articles are formed.

Also, in the embodiments described above, the sealing resin is removed by a grinder. However, such a step can be conducted by other grinding methods, other polishing methods or etching.

As described above, the present invention uses metal posts, and does not use bonding wires. Accordingly, the present invention can provide highly reliable, small sized stacked level semiconductor devices at low costs, and also methods for manufacturing the same.

What is claimed is:

1. A semiconductor device including a first semiconductor chip having a second semiconductor chip disposed on a surface of the first semiconductor chip, the semiconductor device comprising:
a first metal post that takes out an electrode, formed on a surface of the first semiconductor chip;
a second metal post that takes out an electrode, formed on a surface of the second semiconductor chip; and
a resin that seals the surface of the first semiconductor chip, the first metal post, the second semiconductor chip and the second metal post.

2. The semiconductor device according to claim 1, further comprising mounting external terminals disposed on the first metal post and the second metal post, respectively.

3. The semiconductor device according to claim 1, at least one of the first metal post and the second metal post being formed with a plated film.

4. The semiconductor device according to claim 1, at least one of the first metal post and the second metal post being formed with a metal ball.

5. The semiconductor device according to claim 1, the mounting external terminal being formed with a metal ball.

6. The semiconductor device according to claim 1, the first metal post being connected to a pad formed within the first semiconductor chip through a re-wiring layer, and the second metal post being connected to a pad formed within the second semiconductor chip through a re-wiring layer.

7. A semiconductor device having a plurality of semiconductor chips that are stacked in layer on a surface of a semiconductor chip, the semiconductor device comprising:
a metal post that takes out an electrode, formed on a surface of each of the semiconductor chips; and
a resin that seals the surface of the semiconductor chip and the metal posts.

8. The semiconductor device according to claim 7, further comprising mounting external terminals disposed on the metal posts.

9. The semiconductor device according to claim 7, at least one of the metal posts being formed with a plated film.

10. The semiconductor device according to claim 7, at least one of the metal posts being formed with a metal ball.

11. The semiconductor device according to claim 8, the mounting external terminals being formed with metal balls.

12. The semiconductor device according to claim 7, the metal posts being connected to pads formed within the semiconductor chips through re-wiring layers.

13. The semiconductor device including a first semiconductor chip having a second semiconductor chip disposed on a surface of the first semiconductor chip, the semiconductor device comprising:
a first mounting external terminal formed on the surface of the first semiconductor chip;
a second mounting external terminal formed on a surface of the second semiconductor chip; and
a resin that seals the surface of the first semiconductor chip, the first mounting external terminal, the second semiconductor chip and the second mounting external terminal, surfaces of the first mounting external terminal and the second mounting external terminal being exposed through the resin.

14. The semiconductor device according to claim 13, the first mounting external terminal and the second mounting external terminal being formed with metal balls, respectively.

15. The semiconductor device according to claim 13, the first mounting external terminal being connected to a pad formed within the first semiconductor chip through a re-wiring layer, and the second mounting external terminal being connected to a pad formed within the second semiconductor chip through a re-wiring layer.

16. A method for manufacturing a semiconductor device, the method comprising:
preparing a first semiconductor chip wherein a first metal post that takes out an electrode is formed on a surface thereof and a second semiconductor chip wherein a second metal post takes out an electrode is formed on a surface thereof;
disposing the first semiconductor chip on a supporting substrate through an adhesive layer;
disposing the second semiconductor chip on a surface of the first semiconductor chip through an adhesive layer;
sealing the supporting substrate, the first semiconductor chip, the first metal post, the second semiconductor chip, and the second metal post with a resin; and
removing the resin by a specified amount to expose surfaces of the respective first metal post and second metal post.

17. The method for manufacturing a semiconductor device according to claim 16, further comprising, after the step of exposing, disposing mounting external terminals on surfaces of the respective first metal post and second metal post.

18. A method for manufacturing a semiconductor device, the method comprising:
preparing a semiconductor wafer wherein a first metal post that takes out an electrode is formed on a surface of each of a plurality of chip regions;
preparing a semiconductor chip wherein a second metal post that takes out an electrode is formed on a surface thereof;
disposing the semiconductor chip on each of the chip regions of the semiconductor wafer through an adhesive layer;
sealing the semiconductor wafer, the first metal post, the semiconductor chip and the second metal post with a resin;
removing the resin by a specified amount to expose surfaces of the respective first metal post and second metal post.

19. The method for manufacturing a semiconductor device according to claim 18, further comprising, after the step of exposing, disposing mounting external terminals on surfaces of the respective first metal post and second metal post.

20. The method for manufacturing a semiconductor device according to claim 19, further comprising, after the step of disposing the mounting external terminals, dividing the semiconductor wafer into individual chips.

21. The method for manufacturing a semiconductor device according to claim 18,
the step of preparing the semiconductor wafer including the steps of forming a pad on the semiconductor wafer, forming a re-wiring layer on the pad, and forming the first metal post on the re-wiring layer, and
the step of preparing the semiconductor chip including the steps of forming a pad within the semiconductor chip, forming a re-wiring layer on the pad, and forming the second metal post on the re-wiring layer.

22. A method for manufacturing a semiconductor device, the method comprising:
preparing a semiconductor wafer wherein a first metal ball that takes out an electrode is formed on a surface of each of a plurality of chip regions;
preparing a semiconductor chip wherein a second metal ball that takes out an electrode is formed on a surface thereof;
disposing the semiconductor chip on each of the chip regions of the semiconductor wafer through an adhesive layer;
sealing the semiconductor wafer, the first metal ball, the semiconductor chip and the second metal ball with a resin;
removing the resin by a specified amount to expose surfaces of the respective first metal ball and second metal ball.

23. The method for manufacturing a semiconductor device according to claim 22, further comprising, after the step of exposing, dividing the semiconductor wafer into individual chips.

24. The method for manufacturing a semiconductor device according to claim 22,
the step of preparing the semiconductor wafer including the steps of forming a pad on the semiconductor wafer, forming a re-wiring layer on the pad, and forming the first metal ball on the re-wiring layer, and
the step of preparing the semiconductor chip including the steps of forming a pad within the semiconductor chip, forming a re-wiring layer on the pad, and forming the second metal ball on the re-wiring layer.
